(19) United States
(12) Patent Application Publication
(10) Pub. No.: US 2024/0215342 A1
(43) Pub. Date: Jun. 27, 2024

(54) DISPLAY DEVICE, AND DISPLAY PANEL AND MANUFACTURING METHOD THEREOF

(71) Applicants: HEFEI XINSHENG OPTOELECTRONICS TECHNOLOGY CO., LTD., Anhui (CN); BOE TECHNOLOGY GROUP CO., LTD., Beijing (CN)

(72) Inventors: Yongchao HUANG, Beijing (CN); Jingang FANG, Beijing (CN); Jun CHENG, Beijing (CN); Xinxin WANG, Beijing (CN); Jun LIU, Beijing (CN); Qinghe WANG, Beijing (CN); Leilei CHENG, Beijing (CN); Bin ZHOU, Beijing (CN); Ce ZHAO, Beijing (CN); Liangchen YAN, Beijing (CN)

(21) Appl. No.: 17/915,522

(22) PCT Filed: May 28, 2021
(86) PCT No.: PCT/CN2021/096814

§ 371 Date: Sep. 29, 2022

(51) Int. Cl. H10K 59/126; H10K 59/12; H10K 59/122

(52) U.S. Cl. CPC H10K 59/126; H10K 59/1201; H10K 59/122

(57) ABSTRACT

A display panel includes a substrate, a driving layer and a light-emitting control layer. The driving layer is provided with a plurality of driving transistors arranged into a plurality of transistor rows in a column direction. The light-emitting control layer includes a plurality of light-emitting devices arranged into a plurality of device rows in the column direction, the device rows is spaced apart by the transistor row in the column direction, and the transistor rows is spaced apart by the device row in the column direction. The pixel-defining layer is provided with a plurality of blocking grooves recessed toward the substrate, the plurality of blocking grooves are arranged in the column direction, at least one of the plurality of blocking grooves is arranged between the transistor row and the device row adjacent in the column direction, and a light-shielding layer is arranged in the blocking groove.

### CROSS-REFERENCE TO RELATED APPLICATIONS

This application is based upon International Application No. PCT/CN2021/096814 filed on May 28, 2021, the entire contents thereof are incorporated herein by reference.

### TECHNICAL FIELD

The present disclosure relates to the field of display technology, in particular, to a display device, and a display panel and manufacturing method thereof.

### BACKGROUND

At present, display panels have been widely used in electronic devices such as mobile phones and computers, and the most common display panel is the organic electroluminescence display panel (OLED). In the organic electroluminescence display panel, a plurality of light-emitting devices emit light independently to display images. However, when displaying images, residual images are prone to be generated. That is, in the process of switching images, the elimination of a previous image is delayed, so that it overlaps with a current image and thus affects the display effect.

The above information disclosed in the Background section is only for enhancement of understanding of the background of the present disclosure and therefore it may contain information that does not form the prior art that is already known to a person skilled in the art.

### SUMMARY

An aspect of the present disclosure provides a display panel, including:
a substrate;
a driving layer, arranged on the substrate and having a pixel area and a peripheral area outside the pixel area, the pixel area being provided with a pixel circuit, the pixel circuit including a plurality of driving transistors, the plurality of driving transistors being arranged into a plurality of transistor rows in a column direction, and the transistor row including multiple driving transistors arranged in a row direction;
a light-emitting control layer, arranged on a surface of the driving layer away from the substrate and including a pixel-defining layer and a plurality of light-emitting devices defined by the pixel-defining layer, the plurality of light-emitting devices being arranged into a plurality of device rows in the column direction, the device row including multiple light-emitting devices arranged in the row direction, the device rows are spaced apart by the transistor row in the column direction, the transistor rows are spaced apart by the device row in the column direction,
wherein the pixel-defining layer is provided with a plurality of blocking grooves recessed toward the substrate, the plurality of blocking grooves are arranged in the column direction, at least one of the plurality of blocking grooves is arranged between the transistor row and the device row adjacent in the column direction, and a light-shielding layer is arranged in the blocking groove.

In an exemplarily embodiment of the present disclosure, the light-shielding layer covers at least a sidewall of the blocking groove.

In an exemplarily embodiment of the present disclosure, the light-shielding layer further covers a bottom surface of the blocking groove.

In an exemplarily embodiment of the present disclosure, the sidewalls of the blocking groove get closer in a direction toward the substrate.

In an exemplarily embodiment of the present disclosure, the light-emitting device includes:
a first electrode, covered by the pixel-defining layer, the pixel-defining layer being provided with an opening exposing the first electrode;
a light-emitting functional layer, at least partially arranged in the opening and being in contact with the first electrode; and
a second electrode, covering the pixel-defining layer and the light-emitting functional layer, the second electrode being further arranged in the blocking groove, and the light-shielding layer being a portion of the second electrode arranged in the blocking groove.

In an exemplarily embodiment of the present disclosure, the light-emitting control layer further includes:
a color filter layer, arranged on a surface of the driving layer away from the substrate, and including a plurality of filter parts arranged in a one-to-one correspondence with the light-emitting devices; and
a color filter planarization layer, covering the color filter layer,
wherein the light-emitting control layer is arranged on a surface of the color filter planarization layer away from the substrate.

In an exemplarily embodiment of the present disclosure, the color filter planarization layer is provided with a through hole, and an orthographic projection of the blocking groove on the substrate is located within an orthographic projection of the through hole on the substrate.

In an exemplarily embodiment of the present disclosure, each of the blocking grooves includes a first blocking groove, the pixel-defining layer is further arranged in the through hole to form the first blocking groove, and a depth of the first blocking groove is the same as a thickness of the color filter planarization layer.

In an exemplarily embodiment of the present disclosure, each of the blocking grooves includes a second blocking groove, and the second blocking groove penetrates through the pixel-defining layer and the color filter planarization layer in a depth direction to expose the driving layer.

In an exemplarily embodiment of the present disclosure, the device row and the transistor row are arranged alternatively in the column direction;
the transistor row between two adjacent device rows in the column direction is a target transistor row, and the two device rows adjacent to the target transistor row are a first device row and a second device row;
in the column direction, a distance between the first device row and the target transistor row is smaller than a distance between the second device row and the target transistor row; and
the first blocking groove is arranged between the first device row and the target transistor row, and the second blocking groove is arranged between the second device row and the target transistor row.

In an exemplarily embodiment of the present disclosure, the color filter layer further includes:
a plurality of filter strips, arranged in the column direction and blocking the transistor rows in a one-to-one correspondence in a direction perpendicular to the substrate,
wherein the filter strip only can pass monochromatic light.

In an exemplarily embodiment of the present disclosure, the filter strip only can pass red light.

In an exemplarily embodiment of the present disclosure, orthographic projections of the filter strips on the substrate are spaced apart by an orthographic projection of the blocking groove on the substrate in the column direction, and the orthographic projections of the blocking grooves on the substrate are spaced apart by the orthographic projection of the filter strip on the substrate in the column direction.

In an exemplarily embodiment of the present disclosure, the pixel circuit includes:
a first transistor, having a first electrode connected to a data line and a control terminal connected to a first scan line;
a driving transistor, having a control terminal connected to a second electrode of the first transistor, a first electrode connected to a first power supply line, and a second electrode connected to an electrode of the light-emitting device, another electrode of the light-emitting device being connected to a second power supply line;
a second transistor, having a first electrode connected to the second electrode of the driving transistor, a second electrode connected to a sensing line, and a control terminal connected to a second scan line; and
a storage capacitor, connected between the control terminal of the driving transistor and the first electrode of the driving transistor, said another electrode of the light-emitting device being connected to the second power supply line.

In an exemplarily embodiment of the present disclosure, the pixel circuit includes:
a shielding layer, arranged on the substrate and including a first electrode plate and a power supply line spaced apart in the column direction;
a buffer layer, covering the shielding layer;
an active layer, arranged on a surface of the buffer layer away from the substrate, and including a first active part, an intermediate part and a second active part spaced apart and arranged in sequence along the column direction, the first active part being configured to form the control terminal of the second transistor, the intermediate part including a second electrode plate and a third active part connected to a side of the second electrode plate away from the first active part, the third active part being configured to form the control terminal of the driving transistor, the second electrode plate and the first electrode plate at least partially overlapping with each other in a direction perpendicular to the substrate, and the second active part being configured to form the control terminal of the first transistor;
a gate insulating layer, arranged on a surface of the active layer away from the substrate;
a gate layer, arranged on a surface of the gate insulating layer away from the substrate, and including the second scan line, a connection line and the first scan line arranged in the column direction, the second scan line and the first active part partially overlapping with each other in the direction perpendicular to the substrate to form the control terminal of the second transistor, the first scan line and the second active part partially overlapping with each other in the direction perpendicular to the substrate to form the control terminal of the first transistor, the connection line and the third active part partially overlapping with each other in the direction perpendicular to the substrate to form the control terminal of the driving transistor;
an interlayer dielectric layer, covering the gate layer; and
a source-drain layer, arranged on ta surface of the interlayer dielectric layer away from the substrate, and including a first connection part, a second connection part and a third connection part arranged in the column direction, the second connection part including a third electrode plate and an extension part interconnected with each other, the third electrode plate at least partially overlapping with the second electrode plate and the first electrode plate in the direction perpendicular to the substrate, the extension part being connected with the second active part, the first connection part being connected with the first active part, the second electrode plate and the first electrode plate, the first electrode plate, the second electrode plate and the third electrode plate being configured to form the storage capacitor, and the third connection part connecting the third active part and the power supply line.

In an exemplarily embodiment of the present disclosure, the first active part, the third active part and the third connection part are arranged along a straight line extending in the column direction.

In an exemplarily embodiment of the present disclosure, the first connection part includes a first section extending in the row direction and a second section extending in the column direction, an end of the first section is connected to the first active part, another end of the first section is connected to an end of the second section, another end of the second section is connected to the second electrode plate, and one of the first section and the second section is connected to the first electrode plate.

In an exemplarily embodiment of the present disclosure, in the column direction, the first scan line is arranged between the third active part and the power supply line.

In an exemplarily embodiment of the present disclosure, the third connection part connects the third active part and the power supply line across the first scan line in the column direction.

An aspect of the present disclosure provides a method for manufacturing a display panel, including:
forming a driving layer on a substrate, the driving layer having a pixel area and a peripheral area outside the pixel area, the pixel area being provided with a pixel circuit, the pixel circuit including a plurality of driving transistors, the plurality of driving transistors being arranged into a plurality of transistor rows in a column direction, and the transistor row including multiple driving transistors arranged in a row direction;
forming a light-emitting control layer on a surface of the driving layer away from the substrate, the light-emitting control layer including a pixel-defining layer and a plurality of light-emitting devices defined by the pixel-defining layer, the plurality of light-emitting devices being arranged into a plurality of device rows in the column direction, the device row including multiple light-emitting devices arranged in the row direction, and the device row and the transistor row being arranged alternatively in the column direction,
wherein the pixel-defining layer is provided with a plurality of blocking grooves recessed toward the substrate, the plurality of blocking grooves are arranged in the column direction, at least one of the plurality of blocking grooves is arranged between the transistor row and the device row adjacent in the column direction, and a light-shielding layer covering at least a sidewall of the blocking groove is arranged in the blocking groove.

An aspect of the present disclosure provides a display device, including any display panel described above.

It is to be understood that the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of this specification, illustrate embodiments consistent with the present disclosure and together with the description serve to explain the principle of the present disclosure. Obviously, the drawings in the following description are only some embodiments of the present disclosure, and for a person skilled in the art, other drawings may also be obtained from these drawings without creative effort.

FIG. 1 is an arrangement schematic diagram of a device row, a transistor row and a filter strip in a display panel according to an embodiment of the present disclosure.

FIG. 2 is a partial cross-sectional view of a display panel according to an embodiment of the present disclosure.

FIG. 3 is a partial cross-sectional view of a display panel according to another embodiment of the present disclosure.

FIG. 4 is a schematic diagram of a blocking groove in a display panel according to an embodiment of the present disclosure.

FIG. 5 is a schematic diagram of a through hole in a display panel according to an embodiment of the present disclosure.

FIG. 6 is an equivalent circuit diagram of a pixel circuit in a display panel according to an embodiment of the present disclosure.

FIG. 7 is a top view of a pixel circuit in a display panel according to an embodiment of the present disclosure.

FIG. 8 is a top view of a shielding layer of a pixel circuit in a display panel according to an embodiment of the present disclosure.

FIG. 9 is a top view of an active layer of a pixel circuit in a display panel according to an embodiment of the present disclosure.

FIG. 10 is a top view of a gate layer of a pixel circuit in a display panel according to an embodiment of the present disclosure.

FIG. 11 is a top view of a source-drain layer of a pixel circuit in a display panel according to an embodiment of the present disclosure.

FIG. 12 is a top view of a pixel circuit, a filter part and a filter strip in a display panel according to an embodiment of the present disclosure.

### DETAILED DESCRIPTION

Example embodiments will now be described more fully with reference to the accompanying drawings. Example embodiments, however, may be embodied in various forms and should not be construed as limited to the examples set forth herein; rather, these embodiments are provided so that the present disclosure will be thorough and complete, and the concept of example embodiments would be fully conveyed to those skilled in the art. The same reference numerals in the drawings denote the same or similar structures, and thus their detailed descriptions will be omitted. Furthermore, the drawings are merely schematic illustrations of the present disclosure and are not necessarily drawn to scale.

The terms “a”, “an”, “the”, “said” and “at least one of” are used to indicate the presence of one or more elements/components/etc.; the terms “including” and “having” are used to indicate an open-ended inclusive meaning and that additional elements/components/etc. may be present in addition to the listed elements/components/etc. The terms “first”, “second”, “third” and the like are used only as labels and are not intended to limit the number of the objects thereof.

A transistor refers to an element including at least three terminals of a gate electrode, a drain electrode, and a source electrode. A transistor has a channel region between the drain electrode (drain terminal, drain region, or drain) and the source electrode (source terminal, source region, or source), and current may flow through the drain electrode, the channel region, and the source electrode. The channel region refers to a region through which current mainly flows. The gate electrode is a control terminal, a first electrode may be the drain electrode, a second electrode may be the source electrode, or the first electrode may be the source electrode and the second electrode may be the drain electrode. The functions of the “source electrode” and the “drain electrode” may be interchanged when transistors of opposite polarities are used or when the direction of the current changes during circuit operation. Therefore, in this specification, the “source electrode” and the “drain electrode” may be interchanged with each other.

A row direction and a column direction in this text only refer to two directions that are perpendicular to each other, and are not limited to an X direction and a Y direction in the drawings. Those skilled in the art can know that if the posture of the display panel changes, the actual orientations of the row direction and the column direction may vary.

In the related art, an organic electroluminescence display panel generally includes a driving backplane and a light-emitting control layer located on a surface of the driving backplane. The driving backplane has a pixel area and a peripheral area outside the pixel area, and the pixel area is provided with a driving circuit. The driving circuit may include a peripheral circuit located in the peripheral area and a plurality of pixel circuits located in the pixel area, and the peripheral circuit is connected to each pixel circuit. The light-emitting control layer may include a plurality of light-emitting devices, the orthographic projection of each light-emitting device on the driving backplane is located within the pixel area, and the respective light-emitting devices are connected to the respective pixel circuits in a one-to-one correspondence, so that each light-emitting device can be driven independently through the peripheral circuit and the pixel circuit to emit light. Both the peripheral circuit and the pixel circuit include a plurality of transistors. The transistor of the pixel circuit includes a driving transistor connected to the light-emitting device, and the performance of the driving transistor directly affects the light-emitting parameters such as response speed and brightness of the light-emitting device.

When the light-emitting device emits light, the light may irradiate the transistor, and the light irradiation may affect the performance of the transistor. For example, the threshold voltage of the transistor may be shifted due to the light irradiation, which will delay the response speed of the transistor and cause residual images. Especially for metal oxide transistors such as IGZO (indium gallium zinc oxide) transistors, they are seriously affected by light. At the same time, for a display panel using a bottom light-emitting device, the light needs to pass through the driving backplane and thus is prone to irradiate the driving transistor, therefore, the residual image is more prominent.

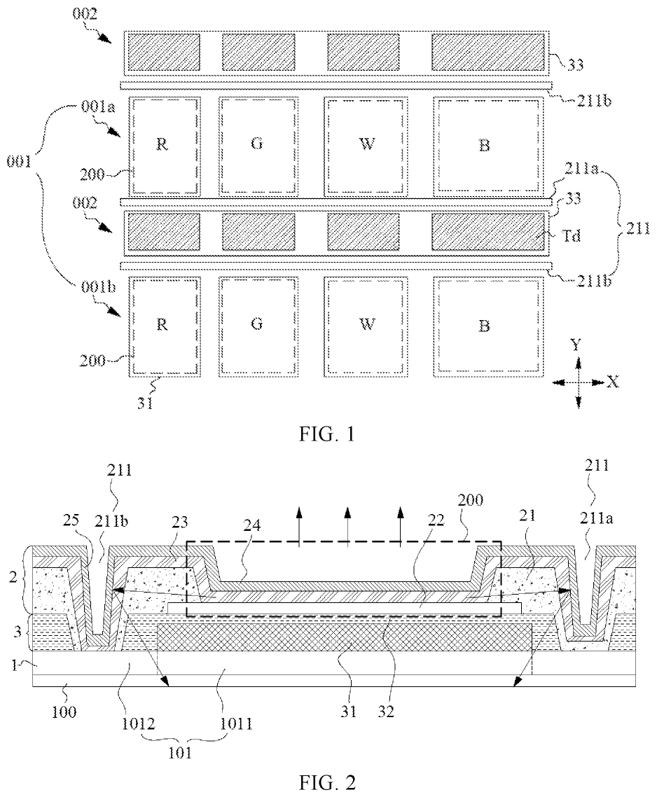

In view of the above-mentioned problems in the related art, an embodiment of the present disclosure provides a display panel. As shown in FIGS. 1-7, the display panel may include a substrate 100, a driving layer 1 and a light-emitting control layer 2.

The driving layer 1 is arranged on the substrate 1, and has a pixel area 101 and a peripheral area outside the pixel area 101. The pixel area 101 is provided with a pixel circuit, and the pixel circuit includes a driving transistor Td. The respective driving transistors Td are arranged into a plurality of transistor rows 002 in a column direction Y, and the transistor row 002 includes multiple driving transistors Td arranged in a row direction X.

The light-emitting control layer 2 is arranged on a surface of the driving layer 1 away from the substrate 100 and includes a pixel-defining layer 21 and a plurality of light-emitting devices 200 defined by the pixel-defining layer 21. The respective light-emitting devices 200 are arranged into a plurality of device rows 001 in the column direction Y, and the device row 001 includes multiple light-emitting devices 200 arranged in the row direction X. The device rows 001 are spaced apart by the transistor row 002 in the column direction Y, and the transistor rows 002 are spaced apart by the device row 001 in the column direction Y.

The pixel-defining layer 21 is provided with a plurality of blocking grooves 211 recessed toward the substrate 100, and the plurality of blocking grooves 211 are arranged in the column direction Y. At least one of the plurality of blocking grooves 211 is arranged between the transistor row 002 and the device row 001 adjacent in the column direction Y, and a light-shielding layer 25 is arranged in the blocking groove 211.

In the display panel according to an embodiment of the present disclosure, the blocking groove 211 is provided between the transistor row 002 and the device row 001, and the blocking groove 211 is covered by the light-shielding layer 25, so that the light-shielding layer 25 in the blocking groove 211 may block and prevent the light emitted by each light-emitting device 200 in device row 001 from directly irradiating the driving transistor Td in the transistor row 002, thereby preventing the threshold voltage of the driving transistor Td from shifting due to the light irradiation, and ensuring the performance of the driving transistor Td not be affected, which in turn is in favour of solving the problem of residual images.

The display panel in the present disclosure may display images, and the related structures are described in detail below.

As shown in FIGS. 2-5, the display panel may include a substrate 100, a driving layer 1 and a light-emitting control layer 2, and the light-emitting control layer 2 may be driven by the driving layer 1 to emit light and thus display an image.

The substrate 100 may be a single-layer or multi-layer structure, and may be a rigid or flexible structure, which is not particularly limited herein.

The driving layer 1 has a driving circuit, through which the light-emitting devices 200 may be driven to emit light independently, so as to display an image.

The driving circuit may include a pixel circuit and a peripheral circuit. At least some of the pixel circuits are arranged in the pixel area 101. Further, part regions of some of the pixel circuits may be arranged in the peripheral area. The number of the pixel circuits is the same as that of the light-emitting devices 200, and the pixel circuits are connected to the light-emitting devices 200 in a one-to-one correspondence, so as to control the respective light-emitting device 200 to emit light independently. The pixel circuit may adopt external compensation and internal compensation. As shown in FIG. 6, the pixel circuit adopting the external compensation may be a 3T1C structure. Taking the pixel circuit of 3T1C adopting the external compensation as an example, it may include a first transistor T1, a second transistor T2, a driving transistor Td and a storage capacitor Cs.

A first electrode of the first transistor T1 is connected to the data line LData, a control terminal of the driving transistor Td is connected to a second electrode of the first transistor T1, and a control terminal of the first transistor T1 may be connected to a first scan line G1. A first electrode of the driving transistor Td is connected to a first power supply line LVDD, and a second electrode of the driving transistor Td is connected to an electrode of the light-emitting device 200. A first electrode of the second transistor T2 is connected to the second electrode of the driving transistor Td, and a second electrode of the second transistor T2 is connected to the sensing line LSense, and a control terminal of the second transistor T2 is connected to a second scan line G2. The storage capacitor Cst is connected between the control terminal and the first electrode 22 of the driving transistor Td, and another electrode of the light-emitting device 200 is connected to the second power line LVSS.

When the light-emitting device 200 is driven to emit light, a scan signal is input through the second scan line G1, a data signal is input through the data line LData, a first power supply signal is input through the first power supply line LVDD, and a second power supply signal is input through the second power supply line LVSS. The first transistor T1 is turned on and the driving transistor Td is turned on, so that the light-emitting device 200 emits light. At the same time, in this process, since the driving transistor Td has a threshold voltage, an external compensation method may be used to eliminate the influence of the threshold voltage. A sensing scan signal may be input through the second scan line G2 to turn on the second transistor T2, and the characteristics such as the threshold voltage and mobility of the driving transistor Td may be determined by detecting the voltage collected by the sensing line LSense, so that the data signal may be updated, to stabilize the light-emitting of the light-emitting device 200. The specific principle of external compensation is not described in detail herein.

Further, the pixel circuit may also use a pixel circuit with internal compensation, which may be a 7T1C, 7T2C, 6T1C, or 6T2C structure as long as the light-emitting device 200 may be driven to emit light, and the structure of the pixel circuit is not limited herein. The expression nTmC herein means that the pixel circuit includes n transistors (represented by the letter “T”) and m capacitors (represented by the letter “C”).

The peripheral circuit is located in the peripheral area, and the peripheral circuit is connected to the pixel circuit for inputting a driving signal to the pixel circuit, so as to control the light-emitting device 200 to emit light. The peripheral circuit may include a gate driving circuit and a source driving circuit, and may also include a sensing circuit and a power supply circuit, and the specific structure of the peripheral circuit is not limited herein.

As shown in FIG. 2 to FIG. 5, the driving layer 1 may be formed by a plurality of film layers. For example, the driving layer 1 may be stacked on a surface of the substrate 100, and the above-mentioned driving circuit may be located in the driving layer. For example, when the transistor in the driving circuit is a top-gate thin film transistor, the driving layer 2 may include a shielding layer 12, a buffer layer 13, an active layer 14, a gate insulating layer 15, a gate layer 16, an interlayer dielectric layer 17, a source-drain layer 18 and a passivation layer 19.

The shielding layer 12 is provided on the substrate 100; the buffer layer 13 covers the shielding layer 12 and the substrate 100; the active layer 14 is provided on the surface of the buffer layer 13 away from the substrate 100; the gate insulating layer 15 is provided on the surface of the active layer 14 away from the substrate 100 and exposes a part of the active layer 14; the gate layer 16 is provided on the surface of the gate insulating layer 15 away from the substrate 100, and includes a plurality of gate electrodes; the interlayer dielectric layer 17 covers the gate electrode, the gate insulating layer 15, the active layer 14 and the substrate 100; the source-drain layer 18 is provided on the surface of the interlayer dielectric layer 17 away from the substrate 100, and includes a plurality of source electrodes 181 and a plurality of drain electrodes 182, the source electrode 181 and the drain electrode 182 may be connected to the area of the active layer 14 not covered by the gate insulating layer 15 through contact holes, thereby forming a plurality of transistors; and the passivation layer 19 may cover the source-drain layer 18 and the interlayer dielectric layer 17. At the same time, a partial area of the light-shielding layer 25 may be disposed opposite to a partial area of the source-drain layer 18, thereby forming the storage capacitor Cst.

Further, the following describes the pattern of a pixel circuit in conjunction with the various film layers of the driving layer 1 above by taking the pixel circuit of 3T1C as an example, as shown in FIGS. 6-12.

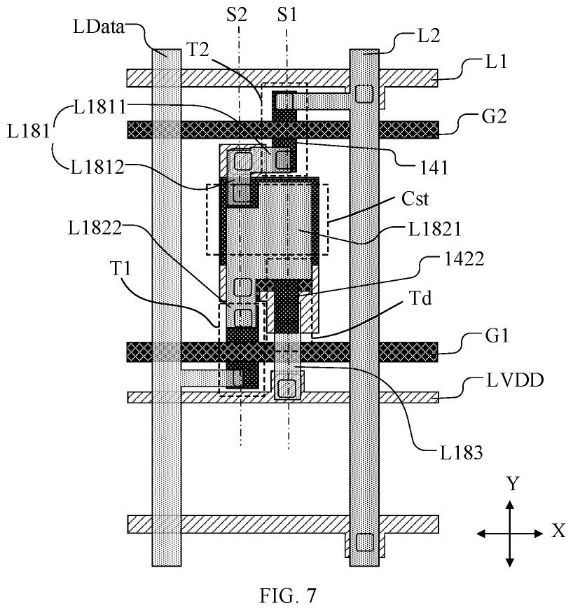

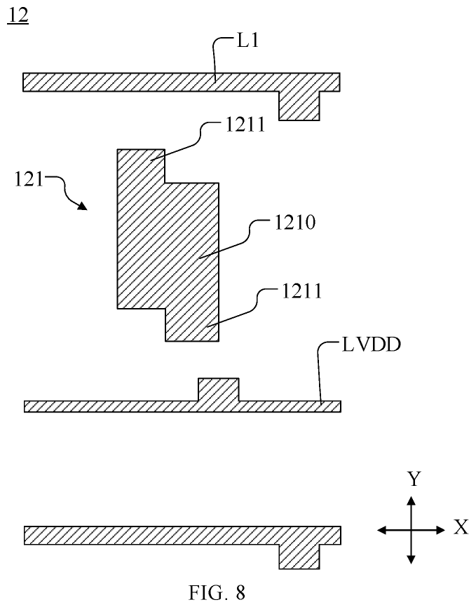

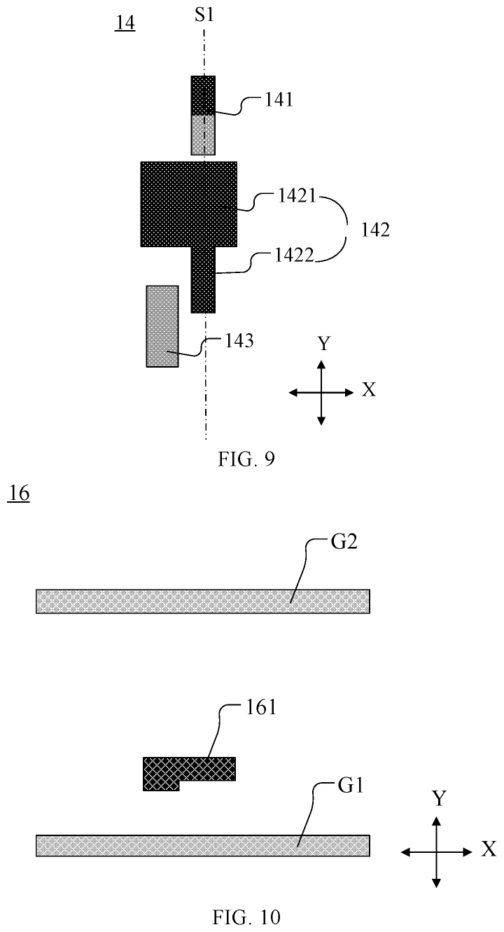

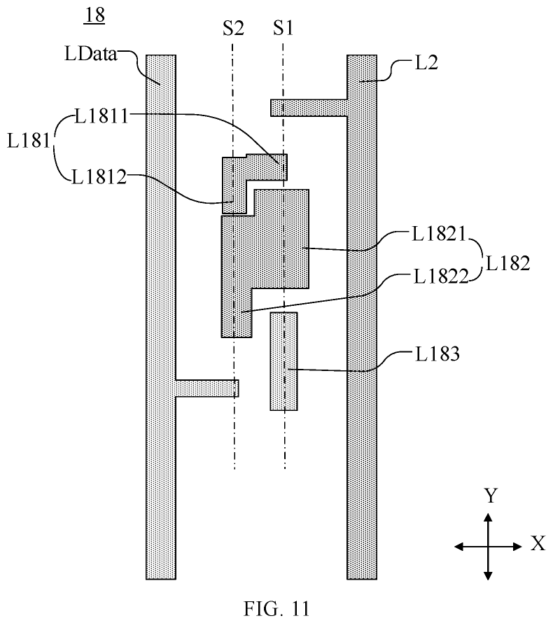

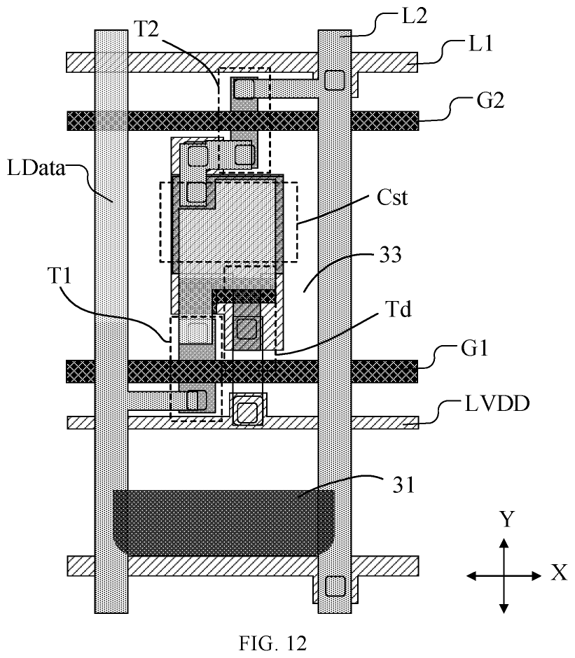

FIG. 7 shows a top view of each film layer in a pixel circuit. FIG. 8 shows a pattern of a shielding layer 12. FIG. 9 shows a pattern of an active layer 14; FIG. 10 shows a pattern of a gate layer 16. FIG. 11 shows a pattern of a source-drain layer 18. FIG. 12 shows a pattern of a pixel circuit, a filter part 31 a filter strip 33.

As shown in FIG. 7 and FIG. 8, the shielding layer 12 includes a first electrode plate 121 and a first power supply line LVDD arranged and spaced apart along the column direction Y.

As shown in FIG. 7 and FIG. 9, the active layer 14 includes a first active part 141, an intermediate part 142 and a second active part 143 sequentially arranged and spaced apart along the column direction Y. The first active part 141 is used to form a control terminal of the second transistors T2. The intermediate part 142 may include a second electrode plate 1421 and a third active part 1422 connected to the side of the second electrode plate 1421 away from the first active part 141. The third active part 1422 is used to form the control terminal of the driving transistor Td. The second electrode plate 1421 and the first electrode plate 121 at least partially overlap with each other in the direction perpendicular to the substrate 100. The second active part 143 is used to form the control terminal of the first transistor T1.

As shown in FIG. 7 and FIG. 10, the gate layer 16 includes a second scan line G2, a connection line 161 and a first scan line G1 arranged along the column direction Y. The second scan line G2 partially overlaps with the first active part 141 in the direction perpendicular to the substrate 100 to form the control terminal of the second transistor T2. The first scan line G1 partially overlaps with the second active part 143 in the direction perpendicular to the substrate 100 to form the control terminal of the first transistor T1. The connection line 161 partially overlaps with the third active part 1422 in the direction perpendicular to the substrate 100 to form the control terminal of the driving transistor Td.

As shown in FIG. 7 and FIG. 11, the source-drain layer 18 includes a first connection part L181, a second connection part L182 and a third connection part L183 arranged along the column direction Y. The second connection part L182 includes a third electrode plate L1821 and an extension part L1822 connected to each other. The third electrode plate L1821 at least partially overlaps with the second electrode plate 1421 and the first electrode plate 121 in the direction perpendicular to the substrate 100. The extension part L1822 is connected with the second active part 143. The first connection part L181 connects the first active part 141, the second electrode plate 1421 and the first electrode plate 121. The first electrode plate 121, the second electrode plate 1421 and the third electrode plate L1821 are used to form the storage capacitor Cst which is a capacitance formed by connecting three plates in parallel. The third connection part L183 connects the third active part 1422 and the first power supply line LVDD.

Further, as shown in FIGS. 7 to 11, the shielding layer 12 may further include a first signal line L1 located at a side of the first electrode plate 121 away from the first power supply line LVDD. The source-drain layer 18 may further include a data line LData and a second signal line L2 arranged along the row direction X, and the first connection part L181, the second connection part L182 and the third connection part L183 are all arranged between the data line LData and the second signal line L2. The data line LData may be connected to the second active part 143 for inputting data signals. The second signal line L2 may be connected to the first active part 141 and the first signal line L1, one of the first signal line L1 and the second signal line L2 may be used as a sensing line LSense to transmit a sensing signal, and the other may be used for inputting reset signals. The sensing signal and the reset signal are transmitted in different periods.

Further, as shown in FIG. 7, in order to increase the capacitance of the storage capacitance Cst, the first electrode plate 121 may have a protrusion 1211 extending along the column direction Y, and there may be a plurality of protrusions 1211, for example two protrusions 1211. For example, the first electrode plate 121 may have a body 1210 and two protrusions 1211, and the two protrusions 1211 are connected to both sides of the body 1210 along the column direction Y, and are arranged along the row direction.

Further, as shown in FIG. 7, FIG. 9 and FIG. 11, the first active part 141, the third active part 1422 and the third connection part L183 are arranged in a straight line S1 extending along the column direction, which can reduce the width of the pixel circuit in the row direction X.

The first connection part L181 includes a first section L1811 extending along the row direction X and a second section L1812 extending along the column direction Y. One end of the first section L1811 is connected to the first active part 141, and the other end thereof is connected to one end of the second section L1812. The other end of the second section L1812 is connected to the second electrode plate 1421. One of the first section L1811 and the second section L1812 is connected to the first electrode plate 121. In addition, the extension part L1822 and the second section L1812 can be arranged in a straight line S2 extending along the column direction, and the straight line S2 and the straight line S1 are parallel, which may further reduce the width of the pixel circuit in the row direction X.

Further, as shown in FIG. 7, in the column direction Y, the first scan line G1 is arranged between the third active part 1422 and the first power supply line LVDD. The third connection part L183 connects the third active part 1422 and the first power supply line LVDD across the first scan line G1 in the column direction Y.

It is noted that the connection between two or more film layers stacked and disposed in the direction perpendicular to the substrate 100 may be achieved through contact holes extending in the direction perpendicular to the substrate 100, and the depth of the contact hole depends on the distance of another film layer between the film layers to be connected. The arrangement, shape and size of the contact holes are not limited specifically.

As shown in FIGS. 2 to 5, the light-emitting control layer 2 is arranged on a surface of the driving layer 1, and includes a plurality of light-emitting devices 200 arranged in an array and a pixel-defining layer 21. Each light-emitting device 200 is located in the pixel area 101.

The pixel-defining layer 21 may be disposed on a surface of the driving layer 1, for example, the pixel-defining layer 21 may be disposed on a surface of the passivation layer 19 away from the substrate 100. The pixel-defining layer 21 is used to separate the respective light-emitting devices 200. Specifically, the pixel-defining layer 21 may be provided with a plurality of openings, and the range defined by each opening is the range of a light-emitting device 200. The shape of the opening, that is, the shape of the outline of the orthographic projection of the opening on the driving layer 1 may be a polygon, a smooth closed curve or other shapes, and the smooth closed curve may be a circle, an ellipse or a ovaloid, etc., which is not specifically limited.

The light-emitting devices 200 may be connected to each pixel circuit in a one-to-one correspondence, so as to emit light under the driving of the driving circuit. For example, the light-emitting device 200 may be connected with the source-drain layer 18, so that it may emit light under the driving of the peripheral circuit and the pixel circuit. The light-emitting device 200 may be an OLED (organic light-emitting diode), which may be a top-emitting or a bottom-emitting structure.

As shown in FIGS. 2-5 and 6, in some embodiments of the present disclosure, by taking a light-emitting device 200 with a bottom-emitting structure as an example, the light-emitting device 200 may include a first electrode 22, a light-emitting functional layer 23 and a second electrode 24 stacked in sequence along a direction away from the driving layer.

The first electrode 22 may be disposed on the same surface as the pixel-defining layer 21, and may be used as an anode of the light-emitting device 200. The openings of the pixel-defining layer 21 expose the respective first electrodes 22 in a one-to-one correspondence. The first electrode 22 is a transparent structure, and may be a single-layer or multi-layer structure. The material of the first electrode 22 may include a transparent conductive material such as ITO (Indium Tin Oxide), IZO (Indium Zinc Oxide). Meanwhile, the first electrode 22 serves as an electrode of the light-emitting device 200 and may be connected to the source electrode 181 or the drain electrode 182 of the driving transistor Td.

The light-emitting functional layer 23 is at least partially disposed in the opening, and may include a hole injection layer, a hole transport layer, a light-emitting material layer, an electron transport layer and an electron injection layer sequentially stacked along a direction away from the driving layer 1. Holes and electrons are combined in the light-emitting material layer to form excitons, and the excitons are radiated into photons, thereby generating visible light. The specific light-emitting principle will not be described in detail here.

The second electrode 24 may cover the light-emitting functional layer 23, and may be used as a cathode of the light-emitting device 200. The second electrode 24 is a light-shielding structure, and may be a single-layer or multi-layer structure, and the material thereof may include one or more of a conductive metal, a metal oxide and an alloy. For example, the material of the second electrode 24 may be Al (aluminum). The second electrode 24 may be used as an electrode of the light-emitting device 200 and may be connected to the second power supply line VSS.

Further, as shown in FIGS. 2 to 5, the respectively light-emitting devices 200 may share the same second electrode 24. Specifically, the second electrode 24 is a continuous conductive layer covering the light-emitting functional layer 23 of each light-emitting device 200, that is, the orthographic projection of the second electrode 24 on the pixel-defining layer 21 covers the respective openings at the same time.

In some embodiments of the present disclosure, a plurality of light-emitting devices 200 that emit light of different colors may be provided, so that color display may be directly realized. In any two light-emitting devices 200 emitting light of different colors, at least some light-emitting film layers of the light-emitting functional layers 23 are spaced apart. For example, the light-emitting functional layers 23 of the light-emitting devices 200 with different light-emitting colors are spaced apart, and the materials thereof are not completely the same; or, in the light-emitting devices 200 with different light-emitting colors, at least the light-emitting material layers are spaced apart, and the materials thereof are different. Different light-emitting devices 200 may emit light of different colors.

In other embodiments of the present disclosure, as shown in FIG. 1 to FIG. 5, the light-emitting functional layers 23 of respective light-emitting devices 200 may be different regions of the same film layer, so that the light-emitting colors of the respective light-emitting devices 200 are the same. At this time, the color display may be realized in conjunction with the filtering effect of a color filter layer 3. For example, the color filter layer 3 may be formed on the driving layer 1, and the light-emitting control layer 2 is located on a surface of the color filter layer 3 away from the driving layer 1. The color filter layer 3 may include a plurality of filter parts 31. Each filter part 31 only allows monochromatic light to pass through. The filter part 31 and the light-emitting device 200 are arranged in a one-to-one correspondence in the direction perpendicular to the driving layer 1, that is, the orthographic projection of each filter part 31 on the driving layer 1 at least partially overlaps with the orthographic projection of only one light-emitting device 200 on the driving layer 1, so that the color of the light may be limited by the filtering effect of the filter part 31. A various types of filter parts 31 may be arranged according to the colors of the light passed, each type of filter part 31 includes a plurality of filter parts 31, and different types of filter parts 31 may pass light of different colors. For example, as shown in FIG. 1, the filter part 31 may include a red filter part R, a blue filter part B and a green filter part G, and may further include a transparent part W. The transparent part W corresponds to the light-emitting device 200, and can transmit the light emitted by the light-emitting device 200 without filtering. If the light-emitting device 200 emits white light, the transparent part W transmits the white light.

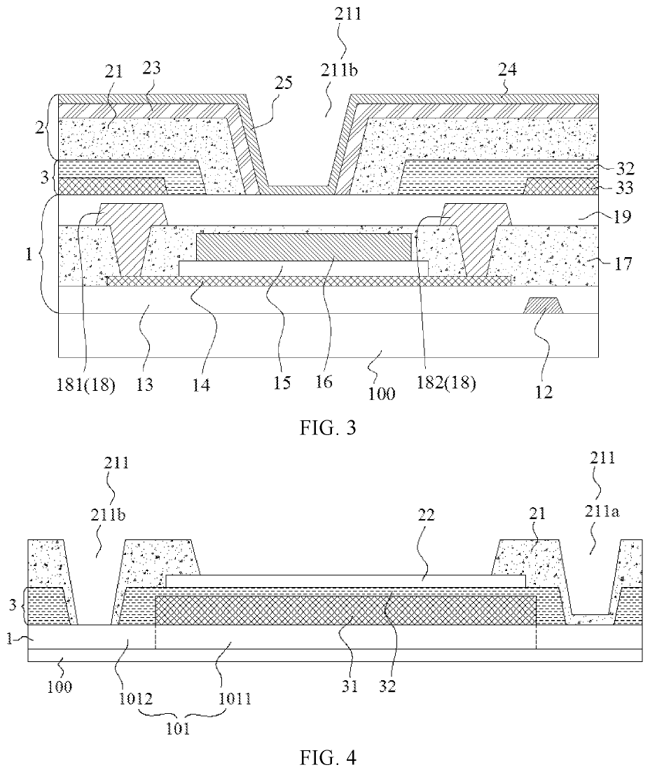

At the same time, as shown in FIG. 2 and FIG. 3, in order to facilitate the arrangement of the light-emitting control layer 2, the color filter layer 3 of transparent material may be covered by a color filter planarization layer 32. The surface of the color filter planarization layer 32 away from the driving layer 1 is flat. The light-emitting control layer 2 may be disposed on the surface of the color filter planarization layer 32 away from the driving layer 1. For example, the first electrode 22 and the pixel-defining layer 21 may be disposed on the surface of the color filter planarization layer 32 away from the driving layer 1.

Further, as shown in FIG. 2, the driving layer 1 may include a transparent area 1011 and a circuit area 1012, and there may a plurality of the transparent areas 1011. The transparent areas 1011 are arranged to correspond to the light-emitting devices 200 in a one-to-one correspondence. The pixel circuit may be arranged in the circuit area 1012, and there is no pixel circuit in the transparent area 1011 to avoid blocking of the light.

In addition, the display panel may further include an encapsulation layer.

The encapsulation layer covers the surface of the light-emitting control layer 2 away from the driving layer 1, and may be used to protect the light-emitting control layer 2 and prevent external water and oxygen from eroding the light-emitting device 200.

In some embodiments of the present disclosure, the encapsulation may be implemented by means of thin-film encapsulation (TFE). Specifically, the encapsulation layer may include a first inorganic layer, an organic layer and a second inorganic layer. The first inorganic layer covers the surface of the light-emitting control layer 2 away from the driving layer 1. The organic layer may be disposed on the surface of the first inorganic layer away from the driving layer 1, and the boundary of the organic layer is limited within the boundary of the first inorganic layer. The second inorganic layer covers the organic layer and the first inorganic layer that is not covered by the organic layer. The second inorganic layer may block water and oxygen, and the flexible organic layer may achieve planarization.

The display panel in the present disclosure may eliminate the residual image by blocking light from irradiating the driving transistor Td, which will be described in detail below.

Based on the above display panel, as shown in FIG. 1, the respective pixel circuits may be arranged in an array along the row direction X and the column direction Y, the respective light-emitting devices 200 may be arranged in an array along the row direction X and the column direction Y, and the driving transistors Td may also be arranged in an array along the row direction X and the column direction Y.

The respective driving transistors Td may be arranged in a plurality of transistor rows 002 along the column direction Y, and each transistor row 002 may include multiple driving transistors Td arranged along the row direction X. The respective light-emitting devices 200 may be arranged in a plurality of device rows 001 along the column direction Y, and each device row 001 includes multiple light-emitting devices 200 arranged along the row direction X.

As shown in FIGS. 2-5, the pixel-defining layer 21 may be provided with a plurality of blocking grooves 211 recessed toward the driving layer 1, and the respective blocking grooves 211 may be arranged along the column direction Y. At least one of the plurality of blocking grooves 211 is arranged between the transistor row 002 and the device row 001 adjacent in the column direction Y, and a light-shielding layer 25 covering at least a sidewall of the blocking groove 211 is provided in the blocking groove 211. The material of the light-shielding layer 25 may be metals such as Al and may also be other light-shielding materials, which is not particularly limited here. When an image is displayed, a portion of the light emitted by the light-emitting device 200 directly exits through the driving layer 1, and another portion of the light propagates toward the transistor row 002, which may be blocked by the light-shielding layer 25 in the blocking groove 211, and thus cannot irradiate the driving transistors Td in the transistor row 002, so as to prevent the performance of the driving transistor Td from being affected by the light.

The blocking groove 211 is further described below.

As shown in FIG. 1 to FIG. 5, the blocking groove 211 is a strip-shaped groove extending along the row direction X, and has a length for shielding all the driving transistors Td in a transistor row 002. For example, the length of the blocking groove 211 along the row direction X is not less than the length of the transistor row 002. The width of the blocking groove 211 along the column direction Y is not particularly limited herein as long as it can block light, and specifically depends on the spacing between the device row 001 and the transistor row 002 adjacent in the column direction Y. In addition, the sidewalls of each of the blocking grooves 211 arranged along the column direction Y may get closer toward the driving layer 1, that is, the spacing between the sidewalls is gradually reduced toward the driving layer 1.

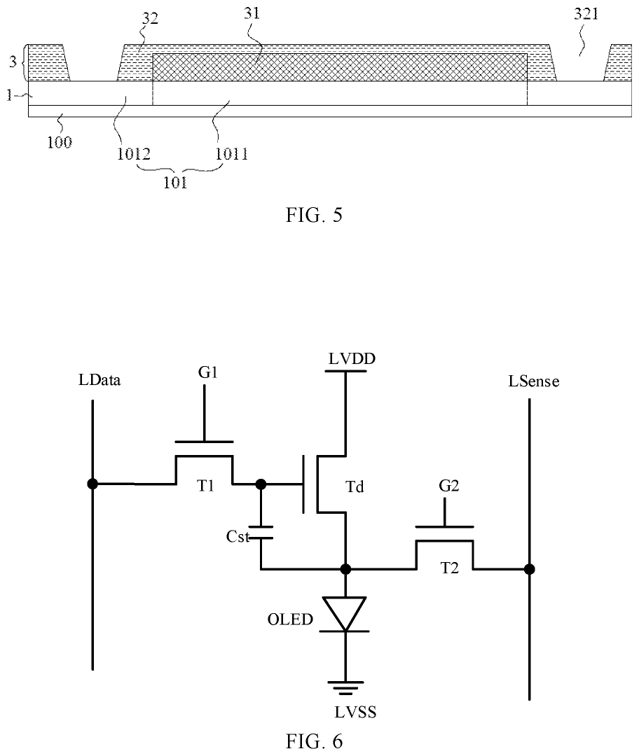

In order to facilitate the formation of the blocking groove 211, as shown in FIGS. 5 and 6, a through hole 321 exposing the driving layer 1 may be formed in the color filter planarization layer 32. The blocking groove 211 is located in the through hole 321, that is, the orthographic projection of the blocking groove 211 on the driving layer 1 is within the orthographic projection of the through hole 321 on the driving layer 1. Meanwhile, the depth of the blocking groove 211 is not particularly limited. For example, the pixel-defining layer 21 is recessed at the through hole 321 to form the blocking groove 211, and at this time, the depth of the blocking groove 211 is the same as that of the color filter planarization layer 32. In an embodiment, the blocking groove 211 may penetrate through the pixel-defining layer 21 along the axis of the through hole 321 to expose the driving layer 1, and at this time, the depth of the blocking groove 211 may be equal to the sum of the thicknesses of the pixel-defining layer 21 and the color filter planarization layer 32. Further, the depth of the blocking groove 211 may also be smaller than the thickness of the color filter planarization layer 32, or the depth of the blocking groove 211 may also be greater than the sum of the thicknesses of the pixel-defining layer 21 and the color filter planarization layer 32, that is, the blocking groove 211 may extend into the driving layer 1. The greater the depth of the blocking groove 211, the greater the range that can block light.

A variety of blocking grooves 211 with different depths may be provided simultaneously in the display panel. Further, the depths of the blocking grooves 211 in the display panel may be the same.

As shown in FIG. 1, due to the complex structure of the pixel circuit, it is difficult to ensure that the transistor row 002 between the two device rows 001 is located between two devices, so that the distances between the transistor row 002 and the device rows 001 on both sides of the transistor row 002 may be different. The space between the transistor row 002 and the device row 001 available for arranging the blocking groove 211 is limited, and it is difficult to limit the light blocking range by changing the position of the blocking groove 211 in the column direction Y. Therefore, the light blocking range of the blocking groove 211 may be limited by the depth of the blocking groove 211, and the deeper the blocking groove 211 is, the larger the light blocking range is.

As shown in FIG. 1, the light-emitting range of the light-emitting device 200 is radial. When the light-emitting ranges of the respective light-emitting devices 200 are the same, if the distance between the transistor row 002 and the device row 001 is large, a deep blocking groove 211 may block the light emitted by the light-emitting device 200, and if the distance between the transistor row 002 and the device row 001 is small, a shallow blocking groove 211 may block the light emitted by the light-emitting device 200. Therefore, the smaller the distance between the transistor row 002 and the device row 001, the smaller the depth of the blocking groove 211 therebetween.

Based on the concept that the light blocking range is defined by the depth of the blocking groove 211, in some embodiments of the present disclosure, the device row 001 and the transistor row 002 are alternately arranged along the column direction Y, that is, in the column direction Y, there is only one transistor row 002 between two adjacent device rows 001, and there is only one device row 001 between two adjacent transistor rows 002.

The transistor row 002 between two device rows 001 adjacent in the column direction Y is a target transistor row 002, and the two device rows 001 adjacent to the target transistor row 002 are a first device row 001a and a second device row 001b respectively.

In the column direction Y, the distance between the first device row 001a and the target transistor row 002 is smaller than the distance between the second device row 001b and the target transistor row 002.

Each blocking groove 211 may include a first blocking groove 211a and a second blocking groove 211b. The first blocking groove 211a penetrates through the pixel-defining layer 21 in the depth direction and exposes the color filter planarization layer 32. The second blocking groove 211b penetrates through the pixel-defining layer 21 and the color filter planarization layer 32 in the depth direction, and exposes the driving layer 1. The first blocking groove 211a is located between the first device row 001a and the target transistor row 002, and the second blocking groove 211b is located between the second device row 001b and the target transistor row 002.

The light-shielding layer 25 is further described below.

As shown in FIGS. 2 to 6, in order to enhance the light-shielding effect and reduce light leakage, on the basis that the light-shielding layer 25 covers the sidewall of the blocking groove 211, the light-shielding layer 25 may also cover the bottom surface of the blocking groove 211, so that all of the inner surface of the groove cannot transmit the light.

Further, in order to simplify the process, a portion of the second electrode 24 of the light-emitting device 200 may be reused as the light-shielding layer 25. For example, the portion of the second electrode 24 corresponding to the pixel-defining layer 21 is recessed/formed into the blocking groove 211, and the light-shielding layer 25 is the portion of the second electrode 24 located in the blocking groove 211, so that the second electrode 24 and the light-shielding layer 25 may be simultaneously formed through one patterning process.

It should be noted that when the sidewall and bottom surface of the blocking groove 211 is covered by the light-shielding layer 25, it refers not only to that the light-shielding layer 25 is directly attached to the sidewall and bottom surface of the blocking groove 211, but also refers to that there may be also another film layer between the light-shielding layer 25 and the sidewall and bottom surface, for example, the light-emitting functional layer 23 of the light-emitting control layer 2 is recessed/formed into the blocking groove 211 and is directly attached to the bottom surface and sidewall of the blocking groove 211, and the second electrode 24 is also recessed/formed into the blocking groove 211 but is directly attached to the light-emitting functional layer 23. That is to say, as long as the light-shielding layer 25 for blocking light is formed on the sidewall and bottom surface of the blocking groove 211, it can be considered that the bottom surface and the sidewall of the blocking groove 211 are covered.

In addition, the light-shielding layer 25 may also be filled in the blocking groove 211. The light-shielding layer 25 may be fully filled in the blocking groove 211. Obviously, the light-shielding layer 25 also covers the bottom surface and sidewall of the blocking groove 211, and can also play a role of blocking light.

In addition to blocking the light by the above-mentioned blocking groove 211, the transistor row 002 may also be blocked by the color filter layer 3 to further prevent the driving transistor Td from being irradiated by light, and an example is illustrated below.

In some embodiments of the present disclosure, the color filter layer 3 further includes a plurality of filter strips 33, and the respective filter strips 33 may be arranged along the column direction Y. Each filter strip 33 extends along the row direction X. The respective filter strips 33 block the respective transistor rows 002 in a one-to-one correspondence in the direction perpendicular to the driving layer 1, that is, the respective transistor rows 002 are located within the orthographic projections of the respective filter strips 33 on the driving layer 1 in a one-to-one correspondence, and each filter strip 33 only blocks one transistor row 002. Meanwhile, the filter strip 33 can only transmit monochromatic light, so as to filter out most of the light and reduce the light irradiated onto the driving transistor Td. The material of the filter strip 33 may be the same as that of the filter part 31, so that the filter trip 33 and the filter part 31 may be formed at the same time, so as to simplify the process. Further, since the influence of red light on the driving transistor Td is smaller than that of the light of other colors on the driving transistor Td, the filter strip 33 may adopt a red filter structure, that is, the filter strip 33 may only transmit red light. Of course, the filter strip 33 for filtering light of other colors can also be adopted.

Further, in order to avoid the overlapping of the light blocking effect of the filter strip 33 and the light blocking effect of the blocking groove 211, the orthographic projection of the filter strip 33 on the driving layer 1 and the orthographic projection of the blocking groove 211 on the driving layer 1 may be spaced apart along the column direction Y, thereby increasing the light blocking range and further blocking the light from irradiating the driving transistor Td.

It should be noted that in the expression in the description, the arrangement of feature i and feature j in the column direction refers to the arrangement of the orthographic projections of feature i and feature j on the substrate, rather than limiting features i and j to be different regions in the same film layer. The features i and j may be pixel circuits, light-emitting devices, filter strips, and the like.

The present disclosure also provides a method for manufacturing a display panel. The display panel may be the display panel according to any of the above-mentioned embodiments, and the structure thereof will not be repeated here. The manufacturing method in the present disclosure may include:
step S110, forming a driving layer on a substrate, the driving layer having a pixel area and a peripheral area outside the pixel area, the pixel area being provided with a pixel circuit, the pixel circuit including a plurality of driving transistors, the plurality of driving transistors being arranged into a plurality of transistor rows in a column direction, and the transistor row including multiple driving transistors arranged in a row direction; and
step S120, forming a light-emitting control layer on a surface of the driving layer away from the substrate, the light-emitting control layer including a pixel-defining layer and a plurality of light-emitting devices defined by the pixel-defining layer, the plurality of light-emitting devices being arranged into a plurality of device rows in the column direction, the device row including multiple light-emitting devices arranged in the row direction, and the device row and the transistor row being alternatively arranged in the column direction.

The pixel-defining layer is provided with a plurality of blocking grooves recessed toward the substrate, the plurality of blocking grooves are arranged in the column direction, at least one of the plurality of blocking grooves is arranged between the transistor row and the device row adjacent in the column direction, and a light-shielding layer covering at least a sidewall of the blocking groove is arranged in the blocking groove.

Further, the manufacturing method may further include:
step S130, forming a color filter layer on a surface of the driving layer away from the substrate, the color filter layer including a plurality of filter parts arranged in a one-to-one correspondence with the light-emitting devices; and
step S140, forming a color filter planarization layer covering the color filter layer.

The light-emitting control layer is arranged on a surface of the color filter planarization layer away from the substrate.

In order to form the blocking groove, a through hole may be formed in the color filter planarization layer. When the pixel-defining layer is formed, the pixel-defining layer may be recessed/formed in the through hole to form the blocking groove. Further, after the pixel-defining layer is formed, the recessed portion of the pixel-defining layer into the through hole may also be removed and thus be penetrated until the driving layer is exposed, thereby obtaining a blocking groove with a greater depth. Further, through holes may also be provided, and through a process such as laser drilling, a groove may be directly formed by opening the pixel-defining layer toward the substrate to obtain a blocking groove. The forming process of the blocking groove is not particularly limited here.

Further, in step S120, in order to simplify the process, the light-shielding layer and the second electrode may be formed through the same patterning process, and the light-shielding layer is a portion of the second electrode recessed into the blocking groove.

It should be noted that although the various steps of the manufacturing method of the present disclosure are described in a specific order in the drawings, this does not require or imply that the steps must be performed in this specific order, or that all of the steps shown must be performed in order to achieve the desired result. Additionally or alternatively, certain steps may be omitted, a plurality of steps may be combined into one step for execution, and/or one step may be decomposed into a plurality of steps for execution, and the like.

The present disclosure also provides a display device, including the display panel according to any of the above-mentioned embodiments, the structure and beneficial effects of which may refer to the above-mentioned embodiments of the display panel, and are not repeated here. The display device may be an electronic device with an image display function, such as a mobile phone, a TV, a tablet computer, etc., which will not be listed one by one here.

Other embodiments of the present disclosure may be easily conceived of by those skilled in the art upon consideration of the specification and practice of the invention disclosed herein. This application is intended to cover any variations, uses, or adaptations of the present disclosure that follow the general principles of the present disclosure and include common knowledge or technical means in the technical field not disclosed by the present disclosure. The specification and examples are to be regarded as exemplary only, with the true scope and spirit of the present disclosure being indicated by the appended claims.

1. A display panel, comprising:
a substrate;
a driving layer, arranged on the substrate and having a pixel area and a peripheral area outside the pixel area, the pixel area being provided with a pixel circuit, the pixel circuit comprising a plurality of driving transistors, the plurality of driving transistors being arranged into a plurality of transistor rows in a column direction, and the transistor row comprising multiple driving transistors arranged in a row direction;
a light-emitting control layer, arranged on a surface of the driving layer away from the substrate and comprising a pixel-defining layer and a plurality of light-emitting devices defined by the pixel-defining layer, the plurality of light-emitting devices being arranged into a plurality of device rows in the column direction, the device row comprising multiple light-emitting devices arranged in the row direction, the device rows being spaced apart by the transistor row in the column direction, the transistor rows being spaced apart by the device row in the column direction,
wherein the pixel-defining layer is provided with a plurality of blocking grooves recessed toward the substrate, the plurality of blocking grooves are arranged in the column direction, at least one of the plurality of blocking grooves is arranged between the transistor row and the device row adjacent in the column direction, and a light-shielding layer is arranged in the blocking groove.

2. The display panel according to claim 1, wherein the light-shielding layer covers at least a sidewall of the blocking groove.

3. The display panel according to claim 2, wherein the light-shielding layer further covers a bottom surface of the blocking groove.

4. The display panel according to claim 1, wherein the sidewalls of the blocking groove get closer in a direction toward the substrate.

5. The display panel according to claim 3, wherein the light-emitting device comprises:
a first electrode, covered by the pixel-defining layer, the pixel-defining layer being provided with an opening exposing the first electrode;
a light-emitting functional layer, at least partially arranged in the opening and being in contact with the first electrode; and
a second electrode, covering the pixel-defining layer and the light-emitting functional layer, the second electrode being further arranged in the blocking groove, and the light-shielding layer being a portion of the second electrode arranged in the blocking groove.

6. The display panel according to claim 1, wherein the light-emitting control layer further comprises:
a color filter layer, arranged on a surface of the driving layer away from the substrate, and comprising a plurality of filter parts arranged in a one-to-one correspondence with the light-emitting devices; and
a color filter planarization layer, covering the color filter layer,
wherein the light-emitting control layer is arranged on a surface of the color filter planarization layer away from the substrate.

7. The display panel according to claim 6, wherein the color filter planarization layer is provided with a through hole, and an orthographic projection of the blocking groove on the substrate is located within an orthographic projection of the through hole on the substrate.

8. The display panel according to claim 7, wherein each of the blocking grooves comprises a first blocking groove, the pixel-defining layer is further arranged in the through hole to form the first blocking groove, and a depth of the first blocking groove is the same as a thickness of the color filter planarization layer.

9. The display panel according to claim 8, wherein each of the blocking grooves comprises a second blocking groove, and the second blocking groove penetrates through the pixel-defining layer and the color filter planarization layer in a depth direction to expose the driving layer.

10. The display panel according to claim 9, wherein
the transistor row between two adjacent device rows in the column direction is a target transistor row, and the two device rows adjacent to the target transistor row are a first device row and a second device row;
in the column direction, a distance between the first device row and the target transistor row is smaller than a distance between the second device row and the target transistor row; and
the first blocking groove is arranged between the first device row and the target transistor row, and the second blocking groove is arranged between the second device row and the target transistor row.

11. The display panel according to claim 6, wherein the color filter layer further comprises:
a plurality of filter strips, arranged in the column direction and blocking the transistor rows in a one-to-one correspondence in a direction perpendicular to the substrate,
wherein the filter strip only passes monochromatic light.

12. The display panel according to claim 11, wherein the filter strip only passes red light.

13. The display panel according to claim 11, wherein orthographic projections of the filter strips on the substrate are spaced apart by an orthographic projection of the blocking groove on the substrate in the column direction, and the orthographic projections of the blocking grooves on the substrate are spaced apart by the orthographic projection of the filter strip on the substrate in the column direction.

14. The display panel according to claim 1, wherein the pixel circuit comprises:
a first transistor, having a first electrode connected to a data line and a control terminal connected to a first scan line;
a driving transistor, having a control terminal connected to a second electrode of the first transistor, a first electrode connected to a first power supply line, and a second electrode connected to an electrode of the light-emitting device, another electrode of the light-emitting device being connected to a second power supply line;
a second transistor, having a first electrode connected to the second electrode of the driving transistor, a second electrode connected to a sensing line, and a control terminal connected to a second scan line; and
a storage capacitor, connected between the control terminal of the driving transistor and the first electrode of the driving transistor.

15. The display panel according to claim 14, wherein the pixel circuit comprises:
a shielding layer, arranged on the substrate and comprising a first electrode plate and a power supply line spaced apart in the column direction;
a buffer layer, covering the shielding layer;
an active layer, arranged on a surface of the buffer layer away from the substrate, and comprising a first active part, an intermediate part and a second active part spaced apart and arranged in sequence along the column direction, the first active part being configured to form the control terminal of the second transistor, the intermediate part comprising a second electrode plate and a third active part connected to a side of the second electrode plate away from the first active part, the third active part being configured to form the control terminal of the driving transistor, the second electrode plate and the first electrode plate at least partially overlapping with each other in a direction perpendicular to the substrate, and the second active part being configured to form the control terminal of the first transistor;
a gate insulating layer, arranged on a surface of the active layer away from the substrate;
a gate layer, arranged on a surface of the gate insulating layer away from the substrate, and comprising the second scan line, a connection line and the first scan line arranged in the column direction, the second scan line and the first active part partially overlapping with each other in the direction perpendicular to the substrate to form the control terminal of the second transistor, the first scan line and the second active part partially overlapping with each other in the direction perpendicular to the substrate to form the control terminal of the first transistor, the connection line and the third active part partially overlapping with each other in the direction perpendicular to the substrate to form the control terminal of the driving transistor;
an interlayer dielectric layer, covering the gate layer; and
a source-drain layer, arranged on ta surface of the interlayer dielectric layer away from the substrate, and comprising a first connection part, a second connection part and a third connection part arranged in the column direction, the second connection part comprising a third electrode plate and an extension part interconnected with each other, the third electrode plate at least partially overlapping with the second electrode plate and the first electrode plate in the direction perpendicular to the substrate, the extension part being connected with the second active part, the first connection part being connected with the first active part, the second electrode plate and the first electrode plate, the first electrode plate, the second electrode plate and the third electrode plate being configured to form the storage capacitor, and the third connection part connecting the third active part and the power supply line.

16. The display panel according to claim 14, wherein the first active part, the third active part and the third connection part are arranged along a straight line extending in the column direction.

17. The display panel according to claim 14, wherein the first connection part comprises a first section extending in the row direction and a second section extending in the column direction, an end of the first section is connected to the first active part, another end of the first section is connected to an end of the second section, another end of the second section is connected to the second electrode plate, and one of the first section and the second section is connected to the first electrode plate.

18. The display panel according to claim 14, wherein in the column direction, the first scan line is arranged between the third active part and the power supply line.

19. The display panel according to claim 18, wherein the third connection part connects the third active part and the power supply line across the first scan line in the column direction.

20. A method for manufacturing a display panel, comprising:
forming a driving layer on a substrate, the driving layer having a pixel area and a peripheral area outside the pixel area, the pixel area being provided with a pixel circuit, the pixel circuit comprising a plurality of driving transistors, the plurality of driving transistors being arranged into a plurality of transistor rows in a column direction, and the transistor row comprising multiple driving transistors arranged in a row direction;
forming a light-emitting control layer on a surface of the driving layer away from the substrate, the light-emitting control layer comprising a pixel-defining layer and a plurality of light-emitting devices defined by the pixel-defining layer, the plurality of light-emitting devices being arranged into a plurality of device rows in the column direction, the device row comprising multiple light-emitting devices arranged in the row direction, and the device row and the transistor row being arranged alternatively in the column direction,
wherein the pixel-defining layer is provided with a plurality of blocking grooves recessed toward the substrate, the plurality of blocking grooves are arranged in the column direction, at least one of the plurality of blocking grooves is arranged between the transistor row and the device row adjacent in the column direction, and a light-shielding layer covering at least a sidewall of the blocking groove is arranged in the blocking groove.

21. (canceled)
